(19) United States
(12) Patent Application Publication
(10) Pub. No.: US 2026/0321212 A1
(43) Pub. Date: Oct. 15, 2026

(54) DISPLAY PANEL AND DISPLAY DEVICE THEREOF

(71) Applicants: Chengdu BOE Optoelectronics Technology Co., Ltd., Chengdu, Sichuan Province (CN); BOE Technology Group Co., Ltd., Beijing (CN)

(72) Inventors: Ting LI, Beijing (CN); Yadong ZHANG, Beijing (CN); Bo WU, Beijing (CN); Baoman LI, Beijing (CN)

(21) Appl. No.: 18/871,187

(22) PCT Filed: Nov. 27, 2023
(86) PCT No.: PCT/CN2023/134383

§ 371 Date: Dec. 3, 2024

(51) Int. Cl. G09G 3/3266; G02F 1/1362; G09G 3/36; H10K 59/123; H10K 59/131; H10K 59/38; H10K 59/80

(52) U.S. Cl. CPC G09G 3/3266; G02F 1/136204; G02F 1/136209; G02F 1/136222; G02F 1/136286; G09G 3/3677; H10K 59/123; H10K 59/131; H10K 59/38; H10K 59/8792; G09G 2300/0408; G09G 2300/0426; G09G 2310/0286; G09G 2330/04

(57) ABSTRACT

Provided in the present disclosure is a display panel and a display device thereof. A display region includes a plurality of sub-pixels, at least one row of sub-pixels includes at least one edge virtual sub-pixel and at least one column of sub-pixels includes at least one edge virtual sub-pixel; a pixel drive unit is configured to drive a first sub-pixel to display a picture; a color film substrate includes a black matrix layer and a color filter layer formed on the color film substrate; the black matrix layer is provided with a plurality of opening regions; an orthographic projection of the first color filter layer, the second color filter layer, and the third color filter layer on the color film substrate overlaps an orthographic projection of the opening regions on the color film substrate.

### CROSS REFERENCE TO RELATED APPLICATION

The present disclosure is a national phase entry under 35 U.S. C § 371 of International Application No. PCT/CN2023/134383, filed on Nov. 27, 2023. The entire content of which is incorporated in the present disclosure by reference.

### TECHNICAL FIELD

The present disclosure relates to the field of display technology, and in particular to a display panel and a display device thereof.

### BACKGROUND

In the field of display technology, for example, a pixel array of a liquid crystal display panel or an organic light-emitting diode (OLED) display panel generally includes a plurality of rows of gate lines and a plurality of columns of data lines interleaved therewith. The driving of the gate lines can be realized by binding the integrated drive circuit. In recent years, as amorphous silicon thin-film transistors or oxide thin-film transistor preparation processes continue to improve, it is also possible to drive the gate lines by directly integrating the gate driver circuit on the thin-film transistor array substrate to form a gate driver on array (GOA). For example, a GOA including a plurality of cascaded shift register units can be used to provide scanning signals for a plurality of rows of gate lines of the pixel array, thereby, for example, controlling the opening of the plurality of rows of gate lines in sequence, and simultaneously providing data signals to the pixel units of the corresponding rows of the pixel array from a data line to form a grayscale voltage required for the grayscale of each gray level of a display image in each of the pixel units, and thereby displaying a frame of an image. Current display panels are increasingly adopting GOA technology to drive the gate lines, which helps to realize narrow border design of the display panels and to reduce the production cost of the display panels.

### SUMMARY

A display panel provided in embodiments of the present disclosure, includes:
a base substrate including a display region and a non-display region; wherein a plurality of sub-pixels are provided in the display region; the plurality of sub-pixels include first sub-pixels and an edge virtual sub-pixel; at least one row of the plurality of sub-pixels includes at least one edge virtual sub-pixel, and at least one column of the plurality of sub-pixels includes at least one edge virtual sub-pixel;
a plurality of pixel drive units in a one-to-one correspondence with the first sub-pixels and the edge virtual sub-pixels; wherein the pixel drive units are configured to drive the first sub-pixels for picture display;
a color film substrate including a black matrix layer and a color filter layer formed on the color film substrate; wherein the black matrix layer is provided with a plurality of opening regions; the color filter layer includes a plurality of first color filter layers, a plurality of second color filter layers and a plurality of third color filter layers; and an orthographic projection of the first color filter layers, the second color filter layers, and the third color filter layers on the color film substrate overlaps an orthographic projection of the opening regions on the color film substrate;
wherein an orthographic projection of the pixel drive unit corresponding to the edge virtual sub-pixel on the base substrate does not overlap an orthographic projection of the first color filter layers, the second color filter layers and the third color filter layers on the base substrate; and the orthographic projection of the pixel drive unit corresponding to the edge virtual sub-pixel on the base substrate does not overlap an orthographic projection of the opening regions on the base substrate.

In some possible embodiments, the edge virtual sub-pixel in a column of sub-pixels is closer to a corner edge of the display region than the first sub-pixels in the column of sub-pixels in a first direction; the edge virtual sub-pixel in a row of sub-pixels is closer to the corner edge of the display region than the first sub-pixels in the row of sub-pixels in a second direction.

In some possible embodiments, a quantity of each column of the opening regions and a quantity of each row of the opening regions both reduce in a direction close to a corner edge of the display region;
wherein the color filter layer includes a plurality of color filter units, each of the color filter units includes: the first color filter layer, the second color filter layer and the third color filter layer; wherein the first color filter layer, the second color filter layer and the third color filter layer in each of the color filter units have the same orthographic projection on the base substrate;
wherein an area of each of the color filter units decreases gradually in the direction close to the corner edge of the display region.

In some possible embodiments, the pixel drive unit includes: a first sub-drive unit, and/or, a second sub-drive unit;
the first sub-drive unit includes a first drive transistor; a gate electrode of the first drive transistor is coupled to a gate line, a first electrode of the first drive transistor is coupled to a data line, and a second electrode of the first drive transistor is coupled to a pixel electrode;
the second sub-drive unit includes a second drive transistor; a gate electrode of the second drive transistor is coupled to the gate line, a first electrode of the second drive transistor is coupled to the data line, and a second electrode of the second drive transistor is coupled to the pixel electrode;
orthographic projections of the plurality of pixel drive units on the base substrate are of the same shape.

In some possible embodiments, sub-pixels close to a corner edge of the display region are arranged in a stepped manner to form a plurality of pixel steps, each pixel step includes at least one sub-pixel; and in some of the pixel steps, at least one edge virtual sub-pixel is provided every other pixel step.

In some possible embodiments, the base substrate further includes: a plurality of cascaded shift register units, a plurality of anti-electrostatic units, and at least one common electrode line; wherein each of the plurality of cascaded shift register units corresponds to one row of the sub-pixels respectively;
an orthographic projection of the anti-electrostatic units on the base substrate and an orthographic projection of the cascaded shift register units on the base substrate are respectively located on different sides of an orthographic projection of the common electrode line on the base substrate; the orthographic projection of the anti-electrostatic units on the base substrate is located between the orthographic projection of the common electrode line on the base substrate and an orthographic projection of the sub-pixels on the base substrate;
the sub-pixels in each pixel step are electrically connected to at least one of the anti-electrostatic units respectively; the anti-electrostatic unit is located at an end of the pixel step in a first direction, and the anti-electrostatic unit is located between up to two rows of sub-pixels in a second direction.

In some possible embodiments, the anti-electrostatic unit corresponding to an nth pixel step is located at an end of the nth pixel step in the first direction, wherein n is an integer not less than 1 and i is an integer not less than 1.

In some possible embodiments, the anti-electrostatic unit corresponding to an nth pixel step is located at an end of an (n+i)^{th} pixel step in the first direction, wherein n is an integer not less than 1 and i is an integer not less than 1.

In some possible embodiments, the anti-electrostatic unit corresponding to an n^{th} pixel step includes a first anti-electrostatic unit located at an end of the nth pixel step in the first direction and a first anti-electrostatic unit located at an end of an (n+i)^{th} pixel step in the first direction, wherein n is an integer not less than 1 and i is an integer not less than 1.

In some possible embodiments, the base substrate further includes: a plurality of data conduction signal lines; the sub-pixels in each pixel step are connected to the corresponding anti-electrostatic unit via the data conduction signal lines;

the data conduction signal line is arranged in an S-shape, and/or a folded line shape, and/or a lightning shape.

In some possible embodiments, the shift register unit includes: a first transistor, a second transistor, a third transistor, a fourth transistor, a fifth transistor, a sixth transistor, a seventh transistor, an eighth transistor, a ninth transistor, and a tenth transistor;
wherein the first transistor and the second transistor are opposite each other along the first direction; the third transistor and the fourth transistor are opposite each other along the first direction; an orthographic projection of the third transistor and the fourth transistor on the base substrate is between an orthographic projection of the first transistor on the base substrate and an orthographic projection of the fifth transistor on the base substrate; the sixth transistor and the seventh transistor are opposite each other along the first direction; an orthographic projection of the eighth transistor on the base substrate, an orthographic projection of the ninth transistor on the base substrate, and an orthographic projection of the tenth transistor on the base substrate are spaced apart in sequence in the second direction;
the first transistor, the second transistor, the third transistor, the fourth transistor, the fifth transistor, the sixth transistor, the seventh transistor, the eighth transistor, the ninth transistor, and the tenth transistor each includes a plurality of active layers; the plurality of active layers are spaced apart from each other along the second direction; the plurality of active layers are spaced apart from each other along the second direction by a distance of no more than 3 microns;
a width of the active layer along the second direction is not greater than 5 microns.

In some possible embodiments, the non-display region includes: a silver paste region, a data fan-out line region, and a GOA signal line region;
the data fan-out line region is located between the display region and the GOA signal line region, the GOA signal line region is located between the data fan-out line region and the silver paste region, and the data fan-out line region is adjacent to the GOA signal line region;
a data fan-out signal line includes: a first extension line and a first lift line;
an angle between the first extension line and the first lift line is a first included angle.

In some possible embodiments, the first included angle ranges from 20 degrees to 35 degrees.

In some possible embodiments, the GOA signal line region includes a plurality of GOA signal lines; wherein the GOA signal line includes: a second extension line and a second lift line;
the second extension line is provided in parallel with the first extension line, and the second lift line is provided in parallel with the first lift line.

In some possible embodiments, a starting end of the data fan-out signal line is located on a lower side of the anti-electrostatic unit; the data fan-out signal line includes a first sub-data fan-out signal line and a second sub-data fan-out signal line, wherein an extension direction of a starting end of the first sub-data fan-out signal line has an included angle of not equal to 90 degrees with the second direction, and/or, an extension direction of a starting end of the second sub-data fan-out signal line extends along the first direction.

In some possible embodiments, an orthographic projection of the first sub-data fan-out signal line on the base substrate is closer to the display region than an orthographic projection of the second sub-data fan-out signal line on the base substrate.

In some possible embodiments, further including:
a gate conduction layer, on the base substrate;
a gate insulation layer, on a side of the gate conduction layer facing away from the base substrate;
a semiconductor layer, on a side of the gate insulation layer facing away from the base substrate; the semiconductor layer including a plurality of active layers;
an etch-blocking layer, on a side of the semiconductor layer facing away from the base substrate;
a source-drain layer, on a side of the etch-blocking layer facing away from the base substrate, including data lines, data fan-out lines, GOA signal lines, and data conduction signal lines;
a first insulation layer, on a side of the source-drain layer facing away from the base substrate;
a common electrode layer, on a side of the first insulation layer facing away from the base substrate;
a second insulation layer, on a side of the common electrode layer facing away from the base substrate;
a pixel electrode layer, on a side of the second insulation layer facing away from the base substrate.

In some possible embodiments, further including: a plurality of adapter units; the adapter unit including a first adapter hole and a second adapter hole; wherein the first adapter hole exposes the gate conduction layer, and the second adapter hole exposes the source-drain layer;
the pixel electrode layer and the gate conduction layer are in a jumper connection through the first adapter hole, and the pixel electrode layer and the source-drain layer are in a jumper connection through the second adapter hole.

In some possible embodiments, the adapter unit is further used for connecting the GOA signal line to the shift register unit, and/or the adapter unit is within the shift register unit.

A display device provided in the embodiments of the present disclosure includes the above display panel.

### BRIEF DESCRIPTION OF FIGURES

FIG. 1 shows a schematic diagram of some structures of a display panel in embodiments of the present disclosure.

FIG. 2 shows a schematic diagram of some other structures of a display panel in embodiments of the present disclosure.

FIG. 3 shows a schematic diagram of yet some other structures of a display panel in embodiments of the present disclosure.

FIG. 4 shows a schematic diagram of yet some other structures of a display panel in embodiments of the present disclosure.

FIG. 5 shows a schematic diagram of yet some other structures of a display panel in embodiments of the present disclosure.

FIG. 6 shows a schematic diagram of some structures of a color filter unit in embodiments of the present disclosure.

FIG. 7 shows a schematic diagram of some structures of a pixel drive unit in embodiments of the present disclosure.

FIG. 8 shows a schematic diagram of some other structures of a pixel drive unit in embodiments of the present disclosure.

FIG. 9 shows a schematic diagram of yet some other structures of a display panel in embodiments of the present disclosure.

FIG. 10 shows a schematic diagram of yet some other structures of a display panel in embodiments of the present disclosure.

FIG. 11 shows a schematic diagram of yet some other structures of a display panel in embodiments of the present disclosure.

FIG. 12 shows a schematic diagram of yet some other structures of a display panel in embodiments of the present disclosure.

FIG. 13 shows a schematic diagram of some structures of a shifter register in embodiments of the present disclosure.

FIG. 14 shows some equivalent circuit diagrams of the shifter register in embodiments of the present disclosure.

FIG. 15 shows another schematic diagram of some structures of the shifter register in embodiments of the present disclosure.

FIG. 16 shows a schematic diagram of some other structures of the shifter register in embodiments of the present disclosure.

FIG. 17 shows a schematic diagram of some other structures of the shifter register in embodiments of the present disclosure.

FIG. 18 shows a schematic diagram of some other structures of the shifter register in embodiments of the present disclosure.

FIG. 19 shows a schematic diagram of yet some other structures of a display panel in embodiments of the present disclosure.

FIG. 20 shows a schematic diagram of yet some other structures of a display panel in embodiments of the present disclosure.

FIG. 21 shows a schematic diagram of yet some other structures of a display panel in embodiments of the present disclosure.

FIG. 22 shows a schematic diagram of yet some other structures of a display panel in embodiments of the present disclosure.

FIG. 23 shows a schematic diagram of yet some other structures of a display panel in embodiments of the present disclosure.

FIG. 24 shows a schematic diagram of yet some other structures of a display panel in embodiments of the present disclosure.

FIG. 25 shows a schematic diagram of yet some other structures of a display panel in embodiments of the present disclosure.

### DETAILED DESCRIPTION

In order to make the objects, technical solutions and advantages of embodiments of the present disclosure clearer, the technical solutions of the embodiments of the present disclosure will be described clearly and completely in the following in conjunction with the accompanying drawings of the embodiments of the present disclosure. Obviously, the described embodiments are a part of the embodiments of the present disclosure and not all of the embodiments. And the embodiments and the features in the embodiments of the present disclosure can be combined with each other without conflict. Based on the described embodiments of the present disclosure, all other embodiments obtained by a person of ordinary skill in the art without the need for creative labor are within the protection scope of the present disclosure.

Unless otherwise defined, technical or scientific terms used in the present disclosure shall have the ordinary meaning understood by a person of ordinary skill in the field to which the present disclosure belongs. The terms “first”, “second”, and the like as used in the present disclosure do not indicate any order, number, or significance, but are only used to distinguish different components. The words “including” or “comprising” and the like are intended to mean that the component or object preceded by the word encompasses the components or objects listed after the word and their equivalents, and does not exclude other components or objects. Words such as “connected” or “coupled” are not limited to physical or mechanical connections, but may include electrical connections, whether direct or indirect.

It should be noted that the dimensions and shapes of the figures in the accompanying drawings do not reflect true proportions, but are intended to be illustrative of the present disclosure only. And throughout the same or similar labeling denotes the same or similar elements or elements having the same or similar functions.

In some embodiments of the present disclosure, the display device may include a display panel, a timing controller. Here, the display panel may include a base substrate (i.e., an array substrate). The base substrate may include a display region and a non-display region. The display region may include a plurality of pixel units arranged in an array. Exemplarily, each pixel unit includes a plurality of sub-pixels of different colors. For example, the pixel unit may include a red sub-pixel(s), a green sub-pixel(s), and a blue sub-pixel(s), so that color mixing can be performed by red, green, and blue to achieve color display. Alternatively, the pixel unit may include a red sub-pixel(s), a green sub-pixel(s), and a blue sub-pixel(s), and a white sub-pixel(s), so that color mixing can be performed by red, green, blue, and white to achieve color display. Of course, in practice, the light-emitting color of the sub-pixels in the pixel unit may be designed and determined according to the actual application environment, and is not limited herein.

In some embodiments of the present disclosure, the display region may also include a plurality of gate lines and a plurality of data lines. Each sub-pixel may include a transistor and a pixel electrode. Here, a row of sub-pixels corresponds to a gate line and a column of sub-pixels corresponds to a data line. A gate electrode of the transistor is coupled to a corresponding gate line, a source electrode of the transistor is coupled to a corresponding data line, and a drain electrode of the transistor is coupled to the pixel electrode. It should be noted that the pixel array structure in the present disclosure may also be a double-gate structure, i.e., two gate lines are provided between two adjacent rows of pixels, and this arrangement may reduce the data lines by half, i.e., including the data lines that are disposed between two adjacent columns of pixels, and some do not include the data lines between two adjacent columns of pixels, and the specific pixel arrangement structure and the data lines, and the arrangement of the gate lines are not limited.

In some embodiments of the present disclosure, the non-display region may include a gate drive circuit and a source drive circuit. The gate drive circuit is coupled to the gate lines, respectively, and the source drive circuit is coupled to the data lines, respectively. Further, the timing controller may be coupled to the gate drive circuit and the source drive circuit, respectively. The gate drive circuit is generally provided in the non-display region on the left and right sides of the display panel. Exemplarily, the timing controller may acquire display data of a to-be-displayed picture in the current display frame, and the timing controller may input a control signal to the gate drive circuit, so that the gate drive circuit may output a gate scanning signal to each of the gate lines individually according to the inputted control signal to drive each of the gate lines to control transistors in the coupled sub-pixels to conduct. Further, the timing controller inputs the acquired display data to the source drive circuit so that the source drive circuit may input a data voltage to the coupled data lines according to the input display data, thereby inputting the voltage on the data lines into the sub-pixels via the conducted transistors to charge the sub-pixels, thereby charging the respective sub-pixels with the respective data voltages, and realizing the screen display function.

It should be noted that the display panel in the embodiments of the present disclosure may be a liquid crystal display panel. Exemplarily, the liquid crystal display panel generally includes an upper substrate (e.g., a color film substrate) and a lower substrate (e.g., a base substrate) of a pair of boxes, and liquid crystal molecules encapsulated between the upper substrate (e.g., the color film substrate) and the lower substrate (e.g., the base substrate).

When a screen is displayed, since there is a voltage difference between a data voltage loaded on the pixel electrode of each sub-pixel and a common electrode voltage loaded on the common electrode, the voltage difference can form an electric field, thereby causing the liquid crystal molecules to be deflected under the action of the electric field. As the electric field of different strengths causes the liquid crystal molecules to be deflected to different degrees, thereby leading to different transmittance rates of the sub-pixels to enable the sub-pixels to achieve brightness of different gray scales, thereby realizing the screen display. Of course, the display panel in the embodiments of the present disclosure may also be an OLED display panel, which is not limited herein.

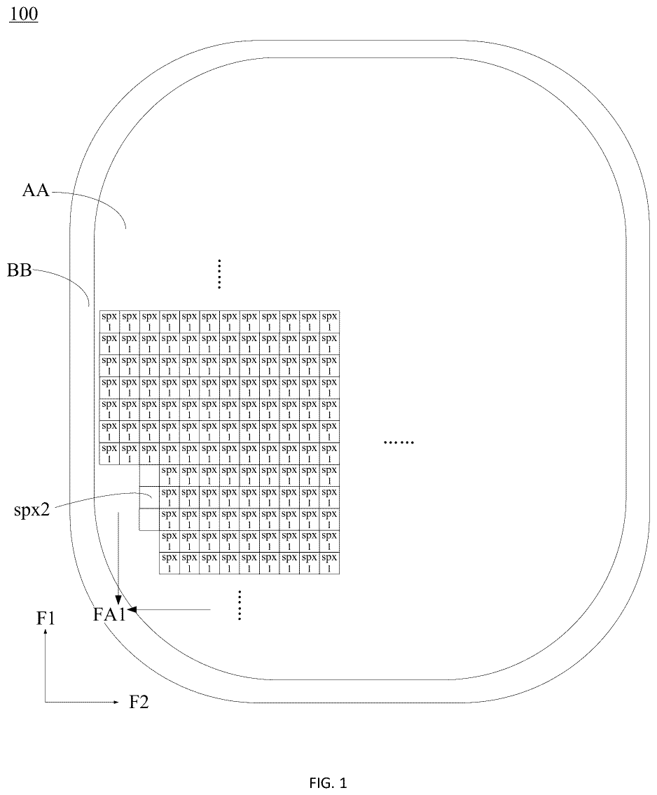

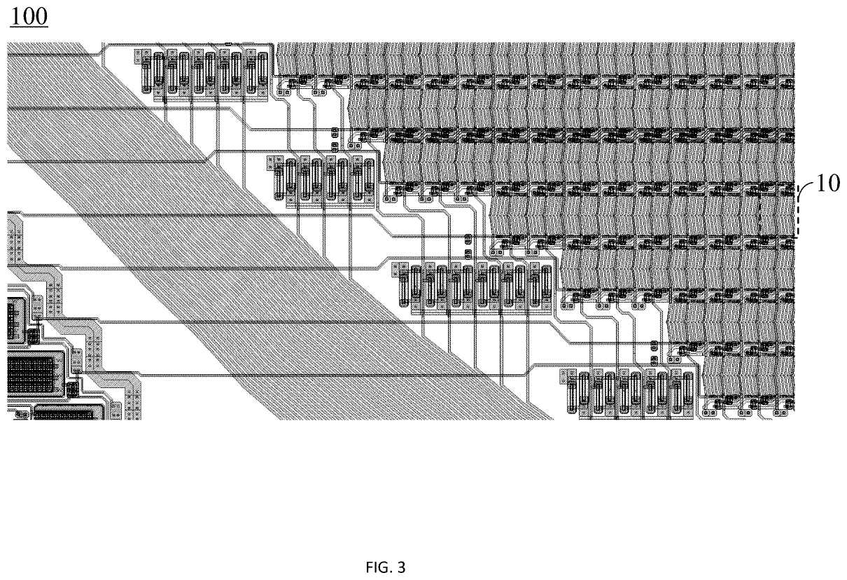

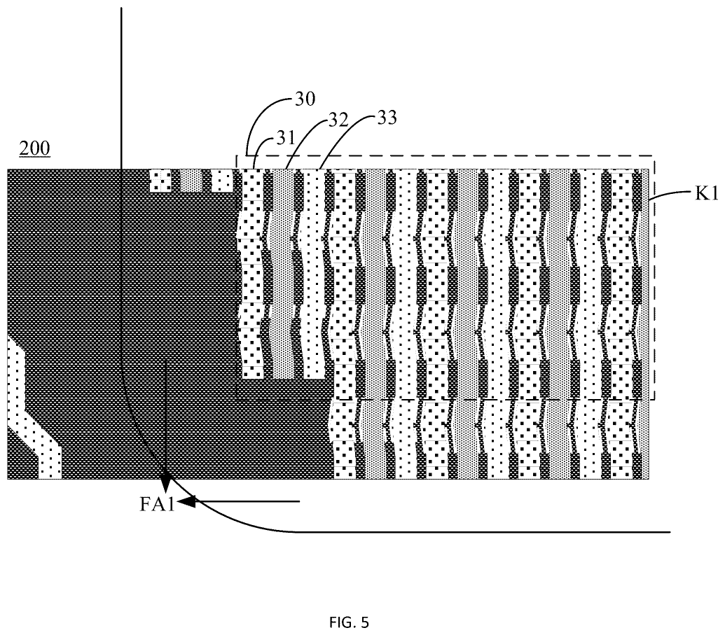

Embodiments of the present disclosure provide a display panel, as shown in FIGS. 1-5, including:
a base substrate 100 including a display region AA and a non-display region BB;
where the display region AA includes a plurality of sub-pixels; the plurality of sub-pixels include first sub-pixels spx1 and edge virtual sub-pixels spx2; at least one row of the sub-pixels has at least one of the edge virtual sub-pixels spx2, and at least one column of sub-pixels has at least one of the edge virtual sub-pixels spx2;
a plurality of pixel drive units 10, in a one-to-one correspondence with the first sub-pixels spx1 and the edge virtual sub-pixels spx2; where the pixel drive units 10 are configured to drive the first sub-pixels spx1 to display a picture;
a color film substrate 200, including a black matrix layer 20 and a color filter layer 30 formed on the color film substrate 200; where the black matrix layer 20 has a plurality of opening regions H1; the color filter layer 30 includes a plurality of first color filter layers 31, a plurality of second color filter layers 32 and a plurality of third color filter layers 33; an orthographic projection of the first color filter layers 31 on the color film substrate, an orthographic projection of the second color filter layers 32 on the color film substrate, and an orthographic projection of the third color filter layers 33 on the color film substrate overlap an orthographic projection of the opening regions H1 on the color film substrate 200.

An orthographic projection of the pixel drive unit 10 corresponding to the edge virtual sub-pixel spx2 on the base substrate 100 does not overlap the orthographic projection of the first color filter layers 31 on the color film substrate, the orthographic projection of the second color filter layers 32 on the color film substrate, and the orthographic projection of the third color filter layers 33 on the base substrate 100; the orthographic projection of the pixel drive unit 10 corresponding to the edge virtual sub-pixel spx2 on the base substrate 100 does not overlap the orthographic projection of the opening regions H1 on the base substrate 100.

In the embodiments of the present disclosure, the orthographic projection of the pixel drive unit corresponding to the edge virtual sub-pixel on the base substrate does not overlap the orthographic projections of the first color filter layers, the second color filter layers, and the third color filter layers on the base substrate; and the orthographic projection of the pixel drive unit corresponding to the edge virtual sub-pixel on the base substrate does not overlap the orthographic projection of the opening regions on the base substrate; so that it does not affect the normal display of the display panel, to thereby improve space utilization and meet the demand for a narrow border of the display panel.

Exemplarily, the orthographic projection of a portion of the pixel drive units on the base substrate does not overlap the orthographic projections of the first color filter layers, the second color filter layers, and the third color filter layers on the base substrate; the orthographic projection of the portion of the pixel drive units on the base substrate does not overlap the orthographic projection of the opening regions on the base substrate; and an orthographic projection of the black matrix layer on the base substrate overlaps the orthographic projection of the portion of the pixel drive units on the base substrate.

Exemplarily, the pixel unit may include red sub-pixels, green sub-pixels, and blue sub-pixels. The red sub-pixels, the green sub-pixels, and the blue sub-pixels in the pixel unit have the same orthographic projection on the base substrate, which are the same as the area of the opening regions corresponding to the red sub-pixels, the green sub-pixels, and the blue sub-pixels. Alternatively, the pixel unit may also include red sub-pixels, green sub-pixels, blue sub-pixels, and white sub-pixels, where the red sub-pixels, the green sub-pixels, the blue sub-pixels, and the white sub-pixels in the pixel unit have the same orthographic projection on the base substrate, which are the same as the area of the opening regions corresponding to the red sub-pixels, the green sub-pixels, the blue sub-pixels, and the white sub-pixels.

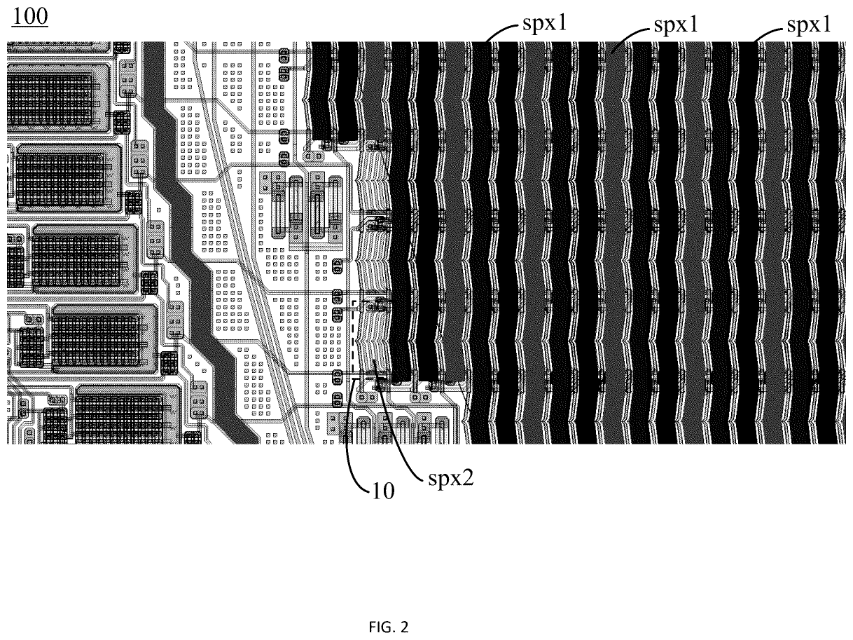

In some embodiments of the present disclosure, as shown in FIGS. 1 and 2, in a first direction F1, the edge virtual sub-pixel spx2 in the same column of the sub-pixels is closer to a corner edge FA1 of the display region than the first sub-pixels spx1; and in a second direction F2, the edge virtual sub-pixel spx2 in the same row of the sub-pixels is closer to the corner edge FA1 of the display region than the first sub-pixel spx1.

Exemplarily, the edge virtual sub-pixels spx2 in the same column of sub-pixels are aligned with the first sub-pixel spx1 along the first direction F1; and the edge virtual sub-pixels spx2 in the same row of sub-pixels are aligned with the first sub-pixel spx1 along the second direction F2.

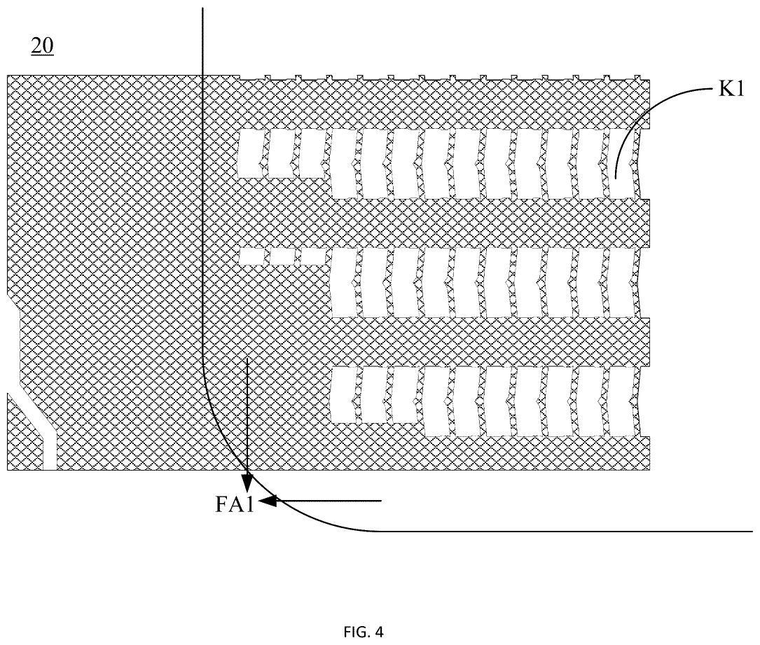

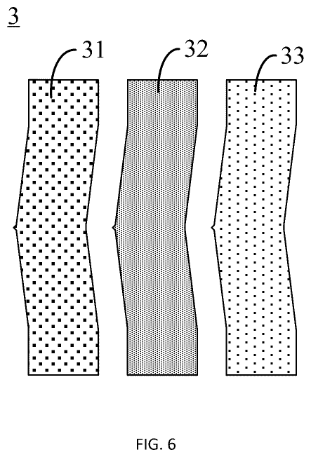

In some embodiments of the present disclosure, as shown in FIGS. 4 to 6, the number of each column of the opening regions H1 and the number of each row of the opening regions H1 reduce in a direction close to the corner edge FA1 of the display region; where the color filter layer 30 includes a plurality of color filter units 3, each color filter unit 3 including: a first color filter layer 31, a second color filter layer 32, and a third color filter layer 33; where the first color filter layer 31, the second color filter layer 32, and the third color filter layer 33 in each color filter unit 3 have the same orthographic projection on the base substrate; where an area of each color filter unit 3 gradually decreases in the direction close to the corner edge FA1 of the display region.

Exemplarily, the opening regions are provided in correspondence with the plurality of color filter units, and the orthographic projections of the first color filter layer, the second color filter layer, and the third color filter layer in each color filter unit on the base substrate overlap the orthographic projection of the opening region on the base substrate; an orthographic projection of an opening region corresponding to a first color filter layer in a color filter unit on the base substrate, an orthographic projection of an opening region corresponding to a second color filter layer in the color filter unit on the base substrate, and an orthographic projection of an opening region corresponding to a third color filter layer in the color filter unit on the base substrate are the same. That is, the opening region corresponding to the first color filter layer in the color filter unit, the opening region corresponding to the second color filter layer in the color filter unit, and the opening region corresponding to the third color filter layer in the color filter unit have approximately the same area and shape.

Exemplarily, as shown in FIG. 4, the area of the opening region H1 in each column and the area of the opening region H1 in each row gradually decrease in a direction close to the corner edge FA1 of the display region AA.

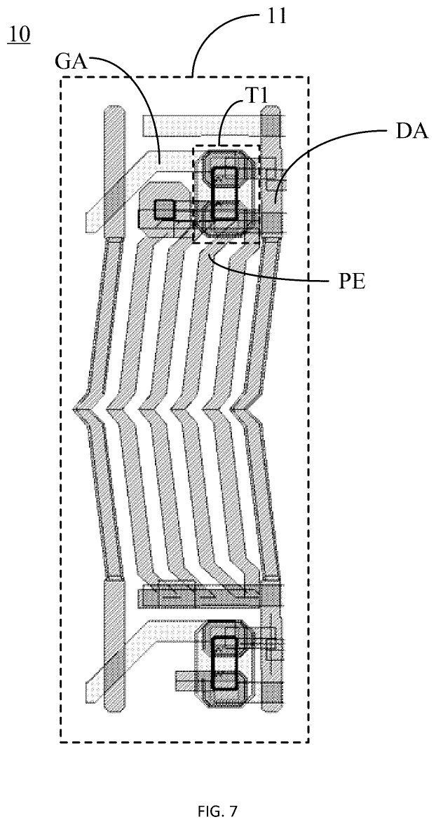

In some embodiments of the present disclosure, as shown in FIG. 7, the pixel drive unit 10 includes: a first sub-drive unit 11; the first sub-drive unit 11 includes a first drive transistor T1; where a gate electrode of the first drive transistor T1 is coupled to a gate line GA, a first electrode of the first drive transistor T1 is coupled to a data line DA, and a second electrode of the first drive transistor T1 is coupled to a pixel electrode PE.

Exemplarily, in the embodiments of the present disclosure, the pixel drive unit can include only the first sub-drive unit, which can further reduce the space occupancy ratio and save space, thereby better realizing a narrow border.

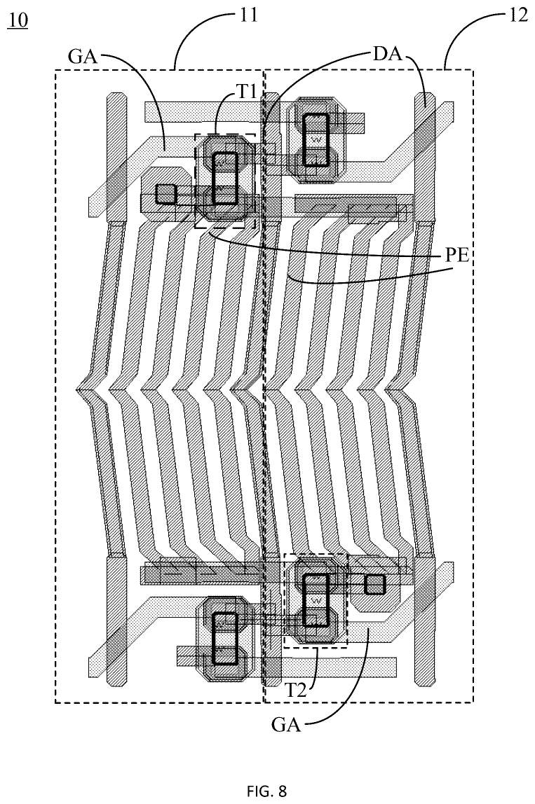

In some embodiments of the present disclosure, as shown in FIG. 8, the pixel drive unit 10 includes: a first sub-drive unit 11 and a second sub-drive unit 12; the second sub-drive unit 12 includes a second drive transistor T2; where a gate electrode of the first drive transistor T1 is coupled to the gate line GA, a first electrode of the first drive transistor T1 is coupled to the data line DA, a second electrode of the first drive transistor T1 is coupled to the pixel electrode PE; the gate electrode of the second drive transistor T2 is coupled to the gate line GA, the first electrode of the second drive transistor T2 is coupled to the data line DA, and the second electrode of the second drive transistor T2 is coupled to the pixel electrode PE; and orthographic projections of the pixel driver units 10 on the base substrate 100 are of the same shape.

Exemplarily, generally in a display panel including Dual-Rate Driving (DRD) technology, the sub-pixels on the base substrate are designed by taking a group including two sub-pixels as a pixel unit; and the color filter layers on the opposite substrate are designed by taking a group including three color filter layers as a color filter unit; where each color filter layer corresponds to a sub-pixel respectively. In the related art, in order to ensure the correspondence between the color filter layers and the sub-pixels and the layout design to be relatively simple, it is usually designed according to the least common multiple of the number of sub-pixels in each pixel unit and the number of color filter layers in each color filter unit; i.e., six sub-pixels are used as a group to be arrayed, and six color filter layers are as a group to be arrayed; this design is relatively simple and easy to be arranged, but it will have a negative impact on corner areas of the display panel (e.g., R corner areas, where the R corner is a rounded corner of an arc tangent to two intersecting straight lines, e.g. the R corner is a rounded corner of the arc tangent to the long side of the display panel and the short side of the display panel), i.e., the border of the corner area of the display panel becomes larger, which affects the aesthetics as well as the realization of the narrow border.

In the embodiments of the present disclosure, the pixel drive unit includes a first sub-drive unit and/or a second sub-drive unit, where each of the first sub-drive unit and the second sub-drive unit corresponds to a sub-pixel; the setting of the pixel drive units for array arrangement is equivalent to the setting of the sub-pixels for array arrangement; when the pixel drive unit includes only the first sub-drive unit or the second sub-drive unit, one sub-pixel is taken as a group for array arrangement; when the pixel driver unit contains the first sub-driver unit and the second sub-driver unit, two sub-pixels are taken as a group for array arrangement. In the present disclosure, the edge virtual sub-pixels are arranged in the border or corner area, which can reduce the number of sub-pixels in the array arrangement and can be easier to control the number of sub-pixels close to the border position, thus facilitating the realization of the narrow border.

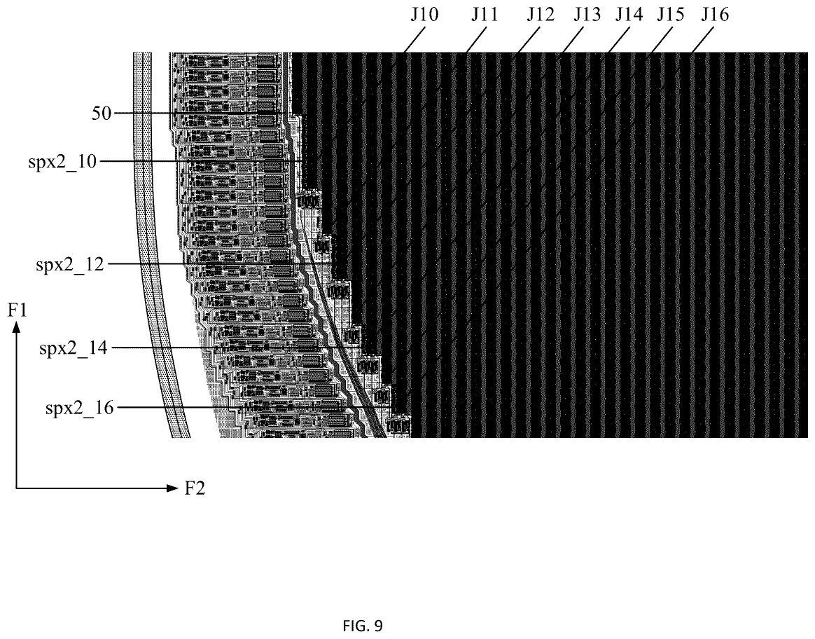

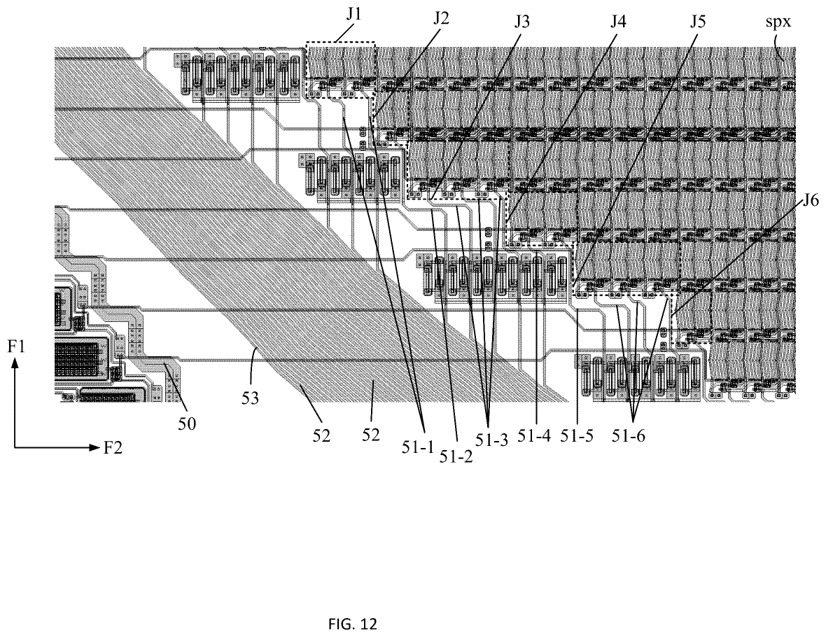

In some embodiments of the present disclosure, as shown in FIGS. 9 to 12, multiple sub-pixels spx close to a corner edge of the display region are arranged in a stepped manner to form a plurality of pixel steps (e.g., J1, J2, J3, J4, J5, J6 in FIG. 12), and each pixel step (e.g., J1, J2, J3, J4, J5, J6 in FIG. 12) includes at least one sub-pixel spx; in some of the pixel steps (e.g., J10, J11, J12, J13, J14, J15, J16 in FIG. 9), at least one edge virtual sub-pixel (e.g., spx2_10, spx2_12, spx2_14, spx2_16 in FIG. 9) is provided every other pixel step.

Exemplarily, as shown in FIG. 9, the pixel step J10 is correspondingly provided with the edge virtual sub-pixel spx2_10; the pixel step J12 is correspondingly provided with the edge virtual sub-pixel spx2_12; the pixel step J14 is correspondingly provided with the edge virtual sub-pixel spx2_14; and the pixel step J16 is correspondingly provided with the edge virtual sub-pixel spx2_16; where the pixel step J10 is separated from the pixel step J12 by one pixel step J11; the pixel step J12 is separated from the pixel step J14 by one pixel step J13; and the pixel step J14 is separated from the pixel step J16 by one pixel step J15; exemplarily, as shown in FIG. 9, the edge virtual sub-pixel spx2_10 is located at an end of the pixel step J10 close to the common electrode line 50; the edge virtual sub-pixel spx2_12 is located at an end of the pixel step J12 close to the common electrode line 50; the edge virtual sub-pixel spx2_14 is located at an end of the pixel step J14 close to the common electrode line 50; and the edge virtual sub-pixel spx2_14 is located at an end of the pixel step J14 close to the common electrode line 50.

In some embodiments of the present disclosure, as shown in FIGS. 9 to 12, the base substrate 100 further includes: a plurality of cascaded shift register units 40, a plurality of anti-electrostatic units ESDs, and at least one common electrode line 50; where each of the plurality of cascaded shift register units 40 corresponds to one row of the sub-pixels spx, respectively.

An orthographic projection of the anti-electrostatic units ESDs on the base substrate 100 and an orthographic projection of the cascaded shift register units 40 on the base substrate 100 are respectively located on different sides of an orthographic projection of the common electrode line 50 on the base substrate 100; the orthographic projection of the anti-electrostatic units ESDs on the base substrate 100 is located between the orthographic projection of the common electrode line 50 on the base substrate 100 and the orthographic projection of the sub-pixels spx on the base substrate 100.

The sub-pixels spx in each pixel step (e.g., J1, J2, J3, J4, J5, J6 in FIG. 12) are electrically connected to at least one anti-electrostatic unit ESD, respectively; the anti-electrostatic unit ESD is located at an end of the pixel step (e.g., J1, J2, J3, J4, J5, J6 in FIG. 12) in a first direction F1, and the anti-electrostatic unit ESD is located between up to two rows of sub-pixels spx in a second direction F2.

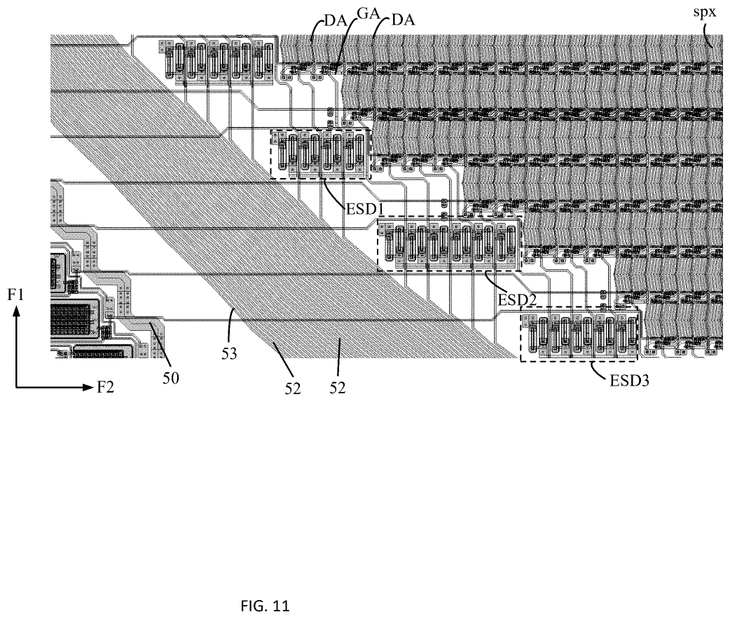

Exemplarily, as shown in FIGS. 11 and 12, the anti-electrostatic unit ESD1 is located at the end of the pixel step J2 in the first direction F1, the anti-electrostatic unit ESD2 is located at the end of the pixel step J4 in the first direction F1; the anti-electrostatic unit ESD3 is located at the end of the pixel step J6 in the first direction F1; the anti-electrostatic unit ESD1, the anti-electrostatic unit ESD2, and the anti-electrostatic unit ESD3 have upper and lower edges in the second direction F2, and the spacing between the two edges is no more than two rows of sub-pixels; that is, the width(s) of the orthographic projection(s) of the anti-electrostatic unit ESD1, the anti-electrostatic unit ESD2, and the anti-electrostatic unit ESD3 on the base substrate in the first direction F1 is(are) less than the width(s) of the orthographic projection(s) of the two rows of sub-pixels on the base substrate in the first direction F1.

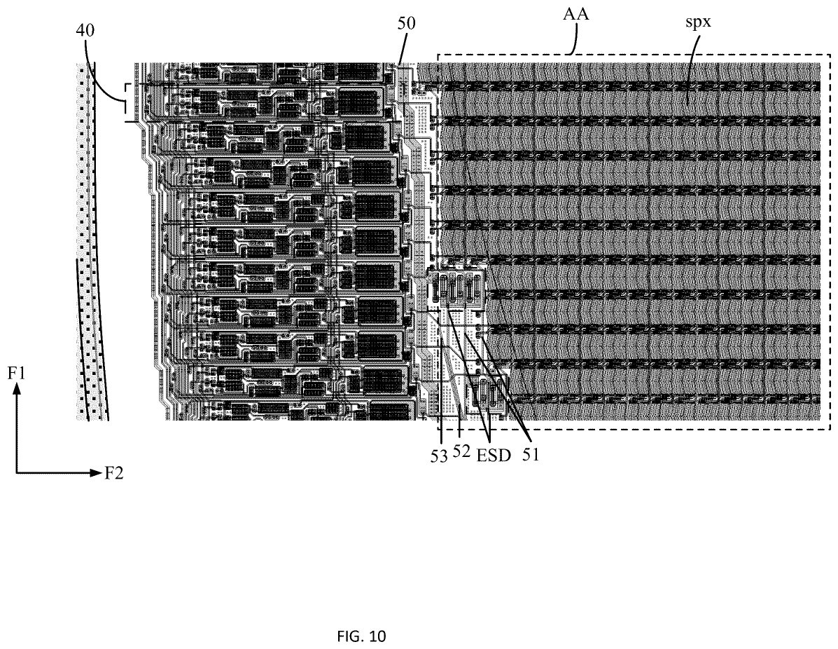

In some embodiments of the present disclosure, as shown in FIGS. 9 to 12, the base substrate 100 further includes: a plurality of data conduction signal lines (e.g., 51 in FIG. 10, 51-1, 51-2, 51-3, 51-4, 51-5, 51-6 in FIG. 12); a sub-pixel spx in each pixel step (e.g., J1, J2, J3, J4, J5, J6 in FIG. 12) is correspondingly connected to an anti-electrostatic unit (e.g., ESD in FIG. 10, ESD1, ESD2, ESD3 in FIG. 11) via a data conduction signal line (e.g., 51 in FIG. 10, 51-1, 51-2, 51-3, 51-4, 51-5, 51-6 in FIG. 12); where the data conduction signal lines (e.g., 51-1, 51-2, 51-3, 51-4, 51-5, 51-6 in FIG. 12) are arranged in an S-shape, and/or a folded line shape, and/or a lightning shape.

In some embodiments of the present disclosure, the anti-electrostatic unit corresponding to an n^{th} pixel step is located at an end of the nth pixel step in the first direction, wherein n is an integer not less than 1 and i is an integer not less than 1.

In some embodiments of the present disclosure, the anti-electrostatic unit corresponding to an nth pixel step is located at an end of an (n+i)^{th} pixel step in the first direction, wherein n is an integer not less than 1 and i is an integer not less than 1.

In some embodiments of the present disclosure, the anti-electrostatic unit corresponding to an n^{th} pixel step comprises a first anti-electrostatic unit located at an end of the nth pixel step in the first direction and a first anti-electrostatic unit located at an end of an (n+i)^{th} pixel step in the first direction, wherein n is an integer not less than 1 and i is an integer not less than 1.

Exemplarily, as shown in FIGS. 11 and 12, the first pixel step J1 is correspondingly provided with the anti-electrostatic unit ESD1 located at the end of the second pixel step J2 in the first direction F1, and the sub-pixels in the first pixel step J1 are correspondingly connected to the anti-electrostatic unit ESD1 via the data conduction signal line 51-1. The second pixel step J2 is correspondingly provided with the anti-electrostatic unit ESD2 located at the end of the fourth pixel step J4 in the first direction F1, and the sub-pixels in the second pixel step J2 are correspondingly connected to the anti-electrostatic unit ESD2 via the data conduction signal line 51-2. The third pixel step J3 is correspondingly provided with the anti-electrostatic unit ESD2 located at the end of the fourth pixel step J4 in the first direction F1, and the sub-pixels in the third pixel step J3 are correspondingly connected to the anti-electrostatic unit ESD2 via the data conduction signal line 51-3. The fourth pixel step J4 is correspondingly provided with the anti-electrostatic unit ESD2 located at the end of the fourth pixel step J4 in the first direction F1 and the fourth pixel step J4 is correspondingly provided with the anti-electrostatic unit ESD3 located at the end of the sixth pixel step J6 in the first direction D1, and a portion of the sub-pixels in the fourth pixel step J4 are correspondingly connected to the anti-electrostatic unit ESD2 via the data conduction signal line 51-4 and a portion of the sub-pixels in the fourth pixel step J4 are correspondingly connected to the anti-electrostatic unit ESD3 via the data conduction signal line 51-5. The fifth pixel step J5 is correspondingly provided with the anti-electrostatic unit ESD3 located at the end of the sixth pixel step J6 in the first direction F1, and the sub-pixels in the fifth pixel step J5 are correspondingly connected to the anti-electrostatic unit ESD3 via the data conduction signal line 51-6.

Exemplarily, as shown in FIGS. 9 to 12, the base substrate 100 further includes a plurality of data fan-out signal lines 52 and a plurality of virtual data fan-out lines 53. The data conduction signal lines (e.g., 51 in FIG. 10, 51-1, 51-2, 51-3, 51-4, 51-5, 51-6 in FIG. 12) are electrically connected to the data fan-out signal lines 52 via the anti-electrostatic units (e.g., ESD in FIG. 10, ESD1, ESD2, ESD3 in FIG. 11). It should be noted that the anti-electrostatic unit (e.g., ESD in FIG. 10, ESD1, ESD2, ESD3 in FIG. 11) prevents electrostatic breakdown caused by a large amount of static electricity gathering, which affects the display quality as well as the display effect. Here, the orthographic projection of the data conduction signal line (e.g., 51 in FIG. 10, 51-1, 51-2, 51-3, 51-4, 51-5, 51-6 in FIG. 12) on the base substrate 100 is located between the orthographic projection of the sub-pixel spx on the base substrate 100 and the orthographic projection of the data fan-out signal line 52 on the base substrate 100; the orthographic projection of the data fan-out signal line 52 on the base substrate is located between the orthographic projection of the anti-electrostatic unit (e.g., ESD in FIG. 10, ESD1, ESD2, ESD3 in FIG. 11) on the base substrate 100 and the orthographic projection of the virtual data fan-out line 53 on the base substrate 100. It should be noted that the virtual fan-out lines can reduce the problem of uneven data fan-out lines close to the shift registers caused by some of the process procedures (e.g., exposure, etching, etc.), mainly the difference in dimensions among the multiple data fan-out lines.

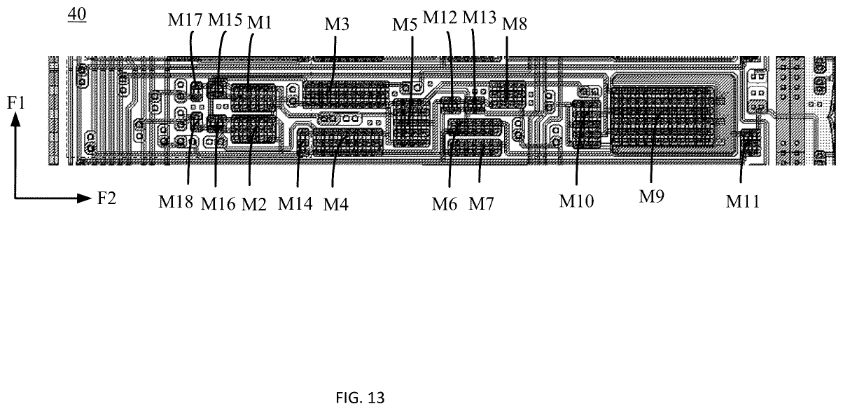

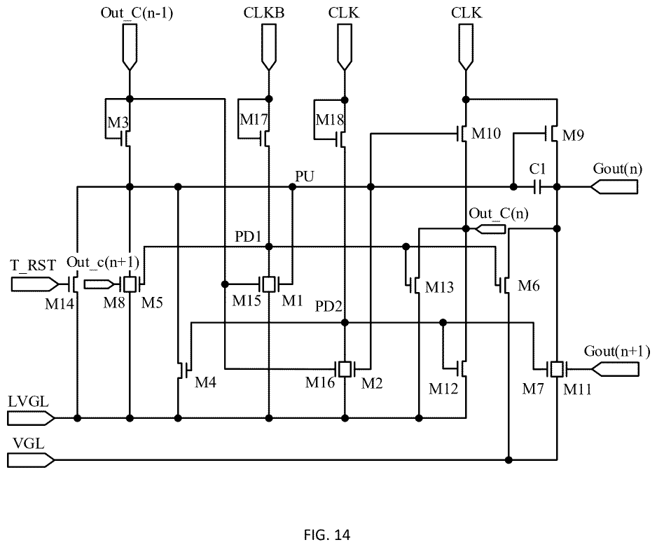

In some embodiments of the present disclosure, as shown in FIGS. 13 and 14, the shift register unit 40 includes: a first transistor M1, a second transistor M2, a third transistor M3, a fourth transistor M4, a fifth transistor M5, a sixth transistor M6, a seventh transistor M7, an eighth transistor M8, a ninth transistor M9, and a tenth transistor M10. The first transistor is provided opposite the second transistor along the first direction F1; the third transistor is provided opposite the fourth transistor along the first direction F1; the orthographic projection(s) of the third transistor and the fourth transistor on the base substrate is(are) located between the orthographic projection of the first transistor on the base substrate and the orthographic projection of the fifth transistor on the base substrate; the sixth transistor is provided opposite the seventh transistor along the first direction F1; the orthographic projections of the eighth transistor, the ninth transistor, and the tenth transistor on the base substrate are arranged at intervals along the second direction F2. For example, the first transistor M1 and the second transistor M2 have the same orthographic projection on the base substrate; the sixth transistor M6 and the seventh transistor M7 have the same orthographic projection on the base substrate.

Exemplarily, as shown in FIGS. 13 and 14, the shift register unit 40 further includes: a twelfth transistor M12, a thirteenth transistor M13, a fourteenth transistor M14, a fifteenth transistor M15, a sixteenth transistor M16, a seventeenth transistor M17, and an eighteenth transistor M18. Here, the twelfth transistor M12 and the thirteenth transistor M13 have the same orthographic projection on the base substrate, and the twelfth transistor M12 and the thirteenth transistor M13 are arranged opposite each other along the second direction F2; the fifteenth transistor M15 and the sixteenth transistor M16 have the same orthographic projection on the base substrate, and are arranged opposite each other along the first direction F1; the seventh transistor M17 and the eighth transistor M18 have the same orthographic projection on the base substrate, and are arranged opposite each other along the first direction F1.

Exemplarily, as shown in the equivalent circuit diagram of the shift register unit of FIG. 14, the gate electrode of the third transistor M3 is coupled to the first electrode of the third transistor M3, the gate electrode of the first transistor M1 is coupled to the third node PU, the first electrode of the first transistor M1 is coupled to the first node PD1, and the second electrode of the first transistor M1 is coupled to the first level signal terminal LVGL; the gate electrode of the second transistor M2 is coupled to the first electrode of the first capacitor C1, the first electrode of the second transistor M2 is coupled to the second node PD2, and the second electrode of the second transistor M2 is coupled to the first level signal terminal LVGL; the first electrode of the third transistor M3 is coupled to the first output control signal terminal Out_C (n−1), and the second electrode of the third transistor M3 is coupled to the first electrode of the eighth transistor M8; the gate electrode of the fourth transistor M4 is coupled to the second node PD2, the first electrode of the fourth transistor M4 is coupled to the second electrode of the third transistor M3, and the second electrode of the fourth transistor M4 is coupled to the first level signal terminal LVGL; the gate electrode of the fifth transistor M5 is coupled to the first node PD1, and the first electrode of the fifth transistor M5 is coupled to the second electrode of the third transistor M3, the second electrode of the fifth transistor M5 is coupled to the first level signal terminal LVGL; the gate electrode of the sixth transistor M6 is coupled to the first node PD1, the first electrode of the thirteenth transistor M13A is coupled to the first cascade output terminal Gout (n), the second electrode of the sixth transistor M6 is coupled to the second level signal terminal VGL; the gate electrode of the seventh transistor M7 is coupled to the second node PD2, the first electrode of the seventh transistor M7 is coupled to the first cascade output terminal Gout (n), the second electrode of the seventh transistor M7 is coupled to the second level signal terminal VGL; the gate electrode of the eighth transistor M8 is coupled to the third output control signal terminal Out_C (n+1), the second electrode of the eighth transistor M8 is coupled to the first level signal terminal LVGL; the gate electrode of the ninth transistor M9 is coupled to the first electrode of the first capacitor C1, and the first electrode of the ninth transistor M9 is coupled to the first clock signal terminal CLK, the second electrode of the ninth transistor M9 is coupled to the first cascade output terminal Gout (n); the second electrode of the first capacitor C1 is coupled to the first cascade output terminal Gout (n); the gate electrode of the tenth transistor M10 is coupled to the first electrode of the first capacitor C1, the first electrode of the tenth transistor M10 is coupled to the first clock signal terminal CLK, the second electrode of the tenth transistor M10 is coupled to the second output control signal terminal Out_C (n); the gate electrode of the eleventh transistor M11 is coupled to the second cascade output terminal Gout (n+1), the first electrode of the eleventh transistor M11 is coupled to the second electrode of the ninth transistor M9, and the second electrode of the eleventh transistor M11 is coupled to the second level signal terminal VGL; the gate electrode of the twelfth transistor M12 is coupled to the second node PD2, the first electrode of the twelfth transistor M12 is coupled to the second output control signal terminal Out_C (n), the second electrode of the twelfth transistor M12 is coupled to the first level signal terminal LVGL; the gate electrode of the thirteenth transistor M13 is coupled to the first node PD1, the first electrode of the thirteenth transistor M13 is coupled to the second output control signal terminal Out_C (n), the second electrode of the thirteenth transistor M13 is coupled to the first level signal terminal LVGL; the gate electrode of the fourteenth transistor M14 is coupled to the reset signal terminal T_RST, the first electrode of the fourteenth transistor M14 is coupled to the second electrode of the first transistor M1, and the second electrode of the fourteenth transistor M14 is coupled to the first level signal terminal LVGL; the gate electrode of the fifteenth transistor M15 is coupled to the first output control signal terminal Out_ C (n−1), the first electrode of the fifteenth transistor M15 is coupled to the first node PD1, the second electrode of the fifteenth transistor M15 is coupled to the first level signal terminal LVGL; the gate electrode of the sixteenth transistor M16 is coupled to the first output control signal terminal Out_C (n−1), the first electrode of the sixteenth transistor M16 is coupled to the second node PD2, and the second electrode of the sixteenth transistor M16 is coupled to the first level signal terminal LVGL; the gate electrode of the seventeenth transistor M17 is coupled to the first electrode of the seventeenth transistor M17, the first electrode of the seventeenth transistor M17 is coupled to the second clock signal terminal CLKB, and the second electrode of the seventeenth transistor M17 is coupled to the first node PD1; the gate electrode of the eighteenth transistor M18 is coupled to the first electrode of the eighteenth transistor M18, the first electrode of the eighteenth transistor M18 is coupled to the first clock signal terminal CLK, and the second electrode of the eighteenth transistor M18 is coupled to the second node PD2.

Exemplarily, the first electrode of the above-described transistor is a source electrode, and the above second electrode is a drain electrode; or the first electrode is a drain electrode and the second electrode is a source electrode, which are not limited herein.

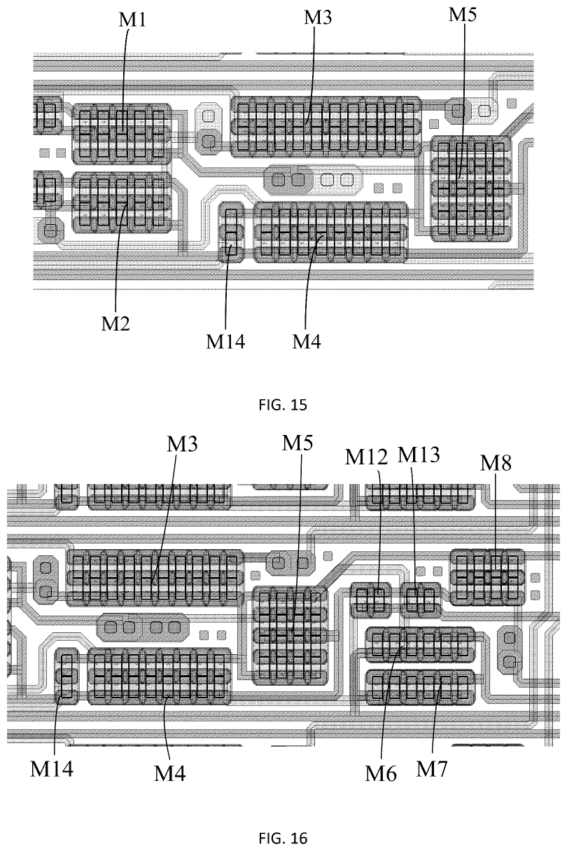

In some embodiments of the present disclosure, as shown in FIGS. 15 to 18, the first transistor, the second transistor, the third transistor, the fourth transistor, the fifth transistor, the sixth transistor, the seventh transistor, the eighth transistor, the ninth transistor, and the tenth transistor each include a plurality of active layers 60; the plurality of active layers 60 are spaced apart from each other along the second direction F2; the plurality of active layers 60 are spaced apart from each other along the second direction F2 by a distance d of no more than 3 microns.

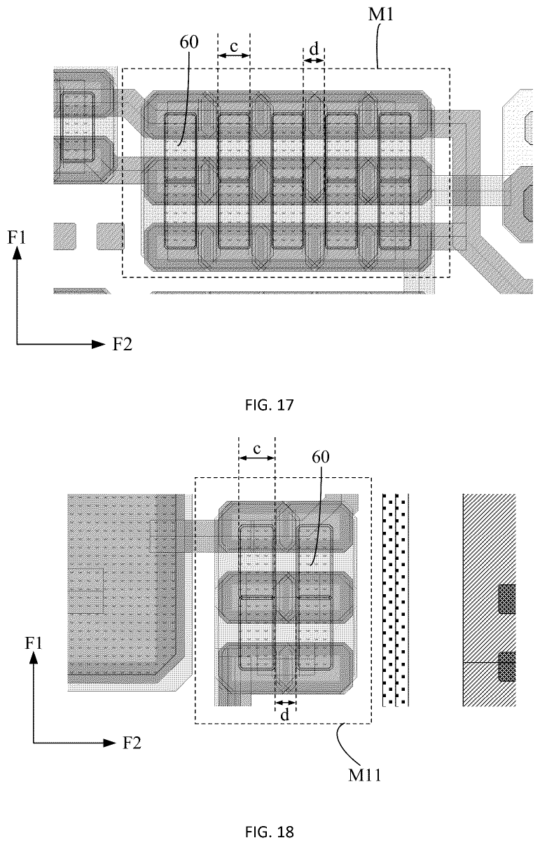

In some embodiments of the present disclosure, as shown in FIGS. 17 and 18, a width(s) c of the plurality of active layers 60 along the second direction F2 is(are) no greater than 5 microns.

Exemplarily, the embodiments of the present disclosure control the spacing of the active layers of the transistors arranged at intervals from each other along the second direction F2 and the width of the active layers by controlling the positions of the transistors in the shift register unit, so that the dimensions of the shift register unit can be reduced, further saving space and making it more convenient to realize a narrow border.

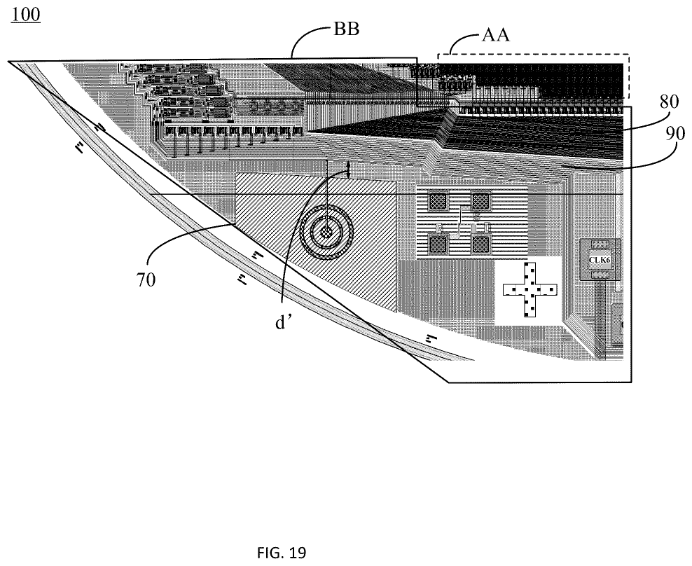

In some embodiments of the present disclosure, as shown in FIGS. 19 to 21, the non-display region BB includes: a silver paste region 70, a data fan-out line region 80, and a GOA signal line region 90; where the data fan-out line region 80 is between the display region AA and the GOA signal line region 90, and the GOA signal line region 90 is between the data fan-out line region 80 and the silver paste region 70, and the data fan-out line region 80 is adjacent to the GOA signal line region 90.

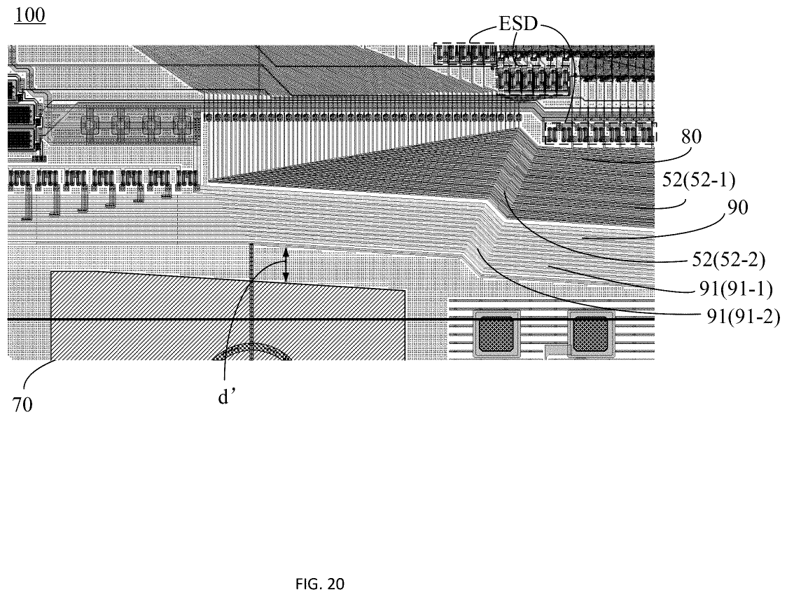

Exemplarily, as shown in FIGS. 19 and 20, a spacing d′ between an edge of the GOA signal line region 90 and an edge of the adjacent silver paste are 70 is not less than 150 microns.

In some embodiments of the present disclosure, as shown in FIGS. 19 to 21, the data fan-out signal line 52 includes: a first extension line 52-1 and a first lift line 52-2; where an angle between the first extension line 52-1 and the first lift line 52-2 is a first included angle e. The GOA signal line region 90 includes a plurality of GOA signal lines 91; where the GOA signal lines 91 include: a second extension line 91-1 and a second lift line 91-2; the second extension line 91-1 is provided in parallel with the first extension line 52-1, and the second lift line 91-2 is provided in parallel with the first lift line 52-2.

Exemplarily, the first included angle e ranges from 20 degrees to 35 degrees. For example, the first included angle e may be 20 degrees, 23 degrees, 26 degrees, 29 degrees, 30 degrees, 35 degrees, etc., which is not limited herein.

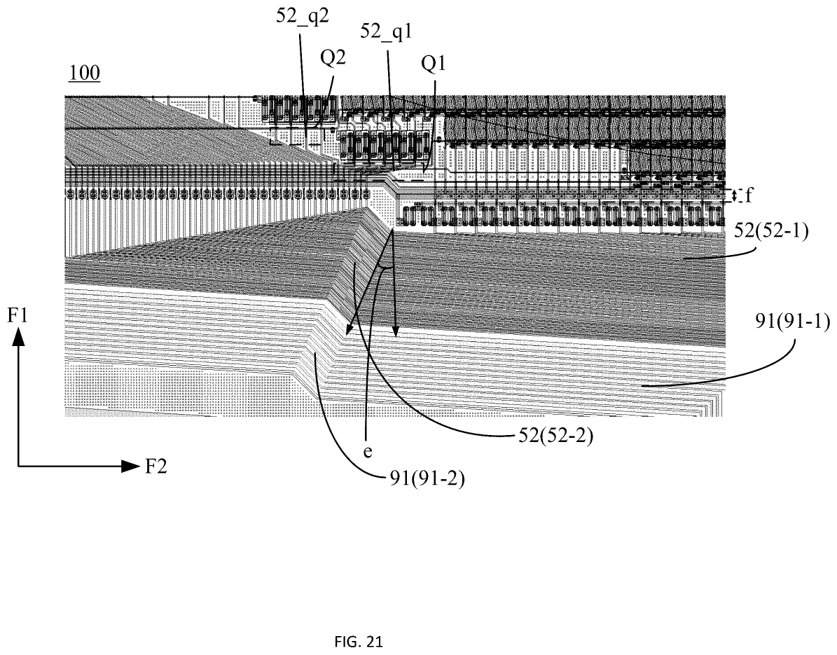

Exemplarily, as shown in FIG. 21, f represents a distance by which the plurality of data fan-out signal lines can be lifted upward.

Exemplarily, the plurality of GOA signal lines in the GOA signal line region may be used for inputting the required signals to the first level signal terminal LVGL, the second level signal terminal VGL, the first output control signal terminal Out_C (n−1), the second output control signal terminal Out_C (n), the third output control signal terminal Out_C (n+1), the first clock signal terminal CLK, and the second clock signal terminal CLKB in the shift register unit, respectively.

In some embodiments of the present disclosure, as shown in FIG. 21, the starting ends (e.g., Q1, Q2 in FIG. 21) of the data fan-out signal line are located on the lower side of the anti-electrostatic unit ESD; the data fan-out signal line includes a first sub-data fan-out signal line 52_q1 and a second sub-data fan-out signal line 52_q2, where the extension direction of the starting end Q1 of the first sub-data fan-out signal line 52_q1 has a 90 degrees of included angle with the second direction F2, and/or, the extension direction of the starting end Q2 of the second sub-data fan-out signal line 52_q2 extends along the first direction F1.

In some embodiments of the present disclosure, as shown in FIG. 21, the orthographic projection of the first sub-data fan-out signal line 52_q1 on the base substrate 100 is closer to the display region than the orthographic projection of the second sub-data fan-out signal line 52_q2 on the base substrate. Optionally, the first sub-data fan-out signal line 52_q1 is electrically connected to an anti-electrostatic unit ESD closest to the data fan-out signal line along the first direction F1.

In the embodiments of the present disclosure, the extension direction of the starting end Q2 of the second sub-data fan-out signal line extends along the first direction F1, and/or, the extension direction of the starting end Q1 of the first sub-data fan-out signal line has an angle not equal to 90 degrees with the second direction F2, where a projection of the first sub-data fan-out signal line on the base substrate is closer to a display region than a projection of the second sub-data fan-out signal line on the base substrate, so that the signal lines such as the common electrode signal line, the data fan-out signal line, the GOA signal line, and so on, have space for setting the lift line, which meet the distance requirement between the silver paste region and the signal lines under the narrow border constraints, to avoid short-circuiting of the signal lines.

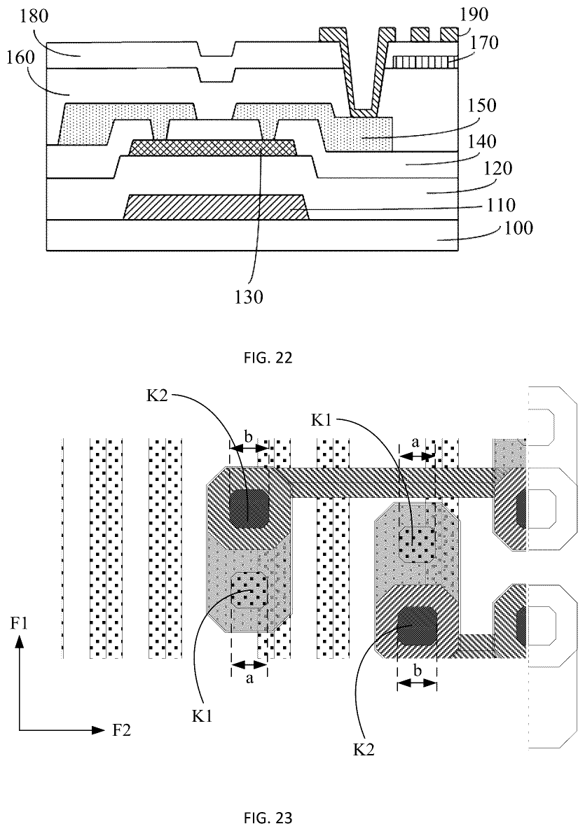

In some embodiments of the present disclosure, as shown in FIG. 22, the display panel further includes:
a gate conduction layer 110, on the base substrate 100;
a gate insulation layer 120, on a side of the gate conduction layer 110 facing away from the base substrate 100;
a semiconductor layer 130, on a side of the gate insulation layer 120 facing away from the base substrate 100; the semiconductor layer 130 including a plurality of active layers;
an etch-blocking layer 140, on a side of the semiconductor layer 130 facing away from the base substrate 100;
a source-drain layer 150, on a side of the etch-blocking layer 140 facing away from the base substrate 100;
a first insulation layer 160, on a side of the source-drain layer 150 facing away from the base substrate 100;
a common electrode layer 170, on a side of the first insulation layer 160 facing away from the base substrate 100;
a second insulation layer 180, on a side of the common electrode layer 170 facing away from the base substrate 100;
a pixel electrode layer 190, on a side of the second insulation layer 180 facing away from the base substrate 100.

Exemplarily, the gate conduction layer may include a gate line as well as a gate electrode of each of the above-described transistors; the source-drain layer may include a data line, a virtual data fan-out signal line, a data fan-out signal line, a GOA signal line, a data conduction signal line, and a source-drain electrode of each of the above-described transistors; the common electrode layer may include a common electrode line; and the pixel electrode layer may include a pixel electrode.

Exemplarily, the material of the gate conduction layer, the source-drain layer, the common electrode layer, and the pixel electrode layer may be a conductive material. For example, the conductive material may include a metal material such as aluminum, molybdenum, titanium, or an alloy material, etc., or a metal oxide, such as indium tin oxide (ITO), etc., and the embodiments of the present disclosure do not limit the materials of the respective functional layers.

Exemplarily, the material of the semiconductor layer may include materials such as oxides, amorphous silicon, or low-temperature polycrystalline silicon, etc., and is not limited herein.

Exemplarily, the gate insulation layer, the etch-blocking layer, the first insulation layer, and the second insulation layer are formed using insulating materials, and as needed, an organic insulation material, such as a material such as a polyimide, a resin material, or an inorganic insulating material, such as a material such as silicon oxide, silicon nitride, and silicon nitride oxide, etc., and the embodiments of the present disclosure do not make a specific limitation on the materials of the various functional layers.

In some embodiments of the present disclosure, as shown in FIGS. 23 to 25, the display panel further includes: a plurality of adapter units (e.g., K1 and K2 in the figures). The adapter unit includes a first adapter hole K1 and a second adapter hole K2. The first adapter hole K1 exposes the gate conduction layer 110 and the second adapter hole K2 exposes the source-drain layer 150. The pixel electrode layer 190 is connected across the gate conduction layer 110 via the first adapter hole K1 and is connected across the source-drain layer 150 via the second adapter hole K2.

Exemplarily, as shown in FIG. 23, the first adapter hole has a width of no greater than 7 microns in the second direction; the second adapter hole has a width of no less than 5 microns in the second direction.

Exemplarily, in the present disclosure, by controlling the size of the first adapter hole K1 and the second adapter hole K2 and combining with the ICP etching process, it can be able to reduce the overall size of all the adapter holes to about 12.5 μm, further realizing a narrow border.

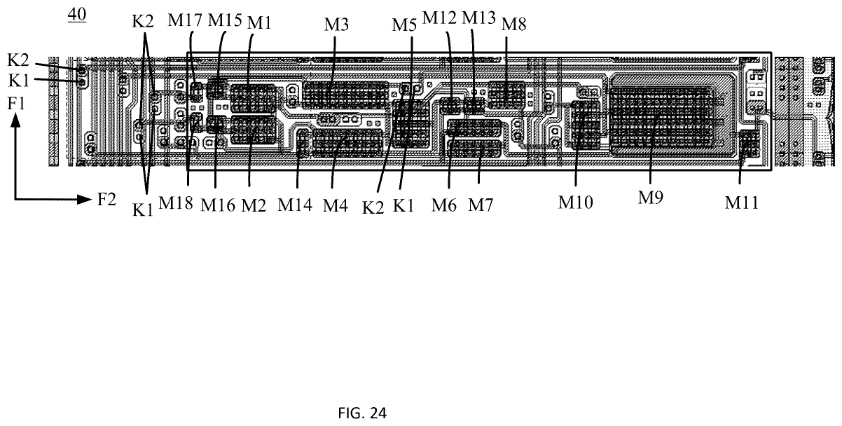

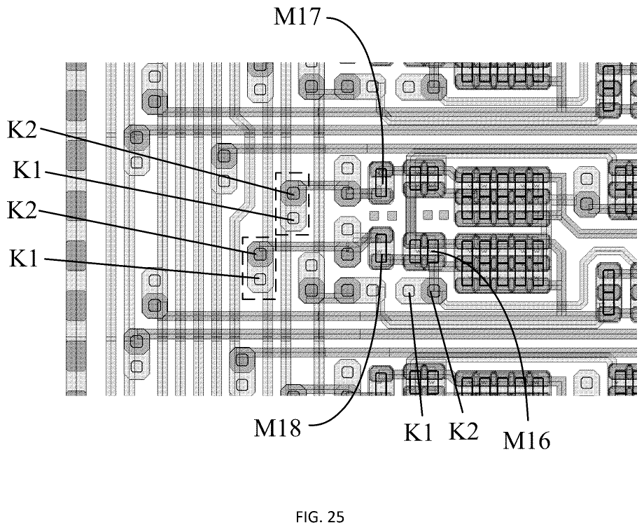

In some embodiments of the present disclosure, as shown in FIGS. 24 and 25, the adapter units (e.g., K1 and K2 in the figures) are also used to connect the GOA signal lines with the shift register unit 40, and/or the adapter units (e.g., K1 and K2 in the figures) are within the shift register unit 40.

Exemplarily, the GOA signal line is connected to the second clock signal terminal CLKB in the shift register unit 40 via the adapter hole, such that the second clock signal terminal CLKB provides the desired signal for the seventeenth transistor M17, and the GOA signal line is connected to the first clock signal terminal CLK in the shift register unit 40 via the adapter hole, such that the first clock signal terminal CLK provides the desired signal for the eighteenth transistor M18.

Exemplarily, the first adapter hole K1 within the shift register unit 40 spans the gate electrode of the sixteenth transistor in the gate conduction layer 110 with the pixel electrode in the pixel electrode layer 190; and the second adapter hole K2 within the shift register unit 40 spans the source-drain electrode of the sixteenth transistor M16 in the source-drain layer 150 with the pixel electrode in the pixel electrode layer 190.

Based on the same concept of the present disclosure, the embodiments of the present disclosure also provide a display device including the above-described display panel in the embodiments of the present disclosure. The display device solves the problem in a similar principle as the aforementioned display panel, so the implementations of the display device can be seen in the implementations of the aforementioned display panel, and the repetition will not be repeated herein.

In specific implementations, in the embodiments of the present disclosure, the display device may be: a cellular phone, an electronic watch, a tablet computer, a television set, a monitor, a laptop computer, a digital photo frame, a navigator, and any other product or component having a display function. Other essential components of the display device should be understood by those of ordinary skill in the art, and are not described herein, nor should they be taken as limitations on the present disclosure.

Although preferred embodiments of the present disclosure have been described, additional changes and modifications may be made to these embodiments once the basic inventive concepts are known to one of skill in the art. Therefore, the appended claims are intended to be construed to include the preferred embodiments as well as all changes and modifications that fall within the scope of the present disclosure.

Obviously, a person skilled in the art may make various changes and variations to the embodiments of the present disclosure without departing from the spirit and scope of the embodiments of the present disclosure. Thus, if such modifications and variations of the embodiments of the present disclosure fall within the scope of the claims of the present disclosure and their technical equivalents, the present disclosure is intended to encompass such modifications and variations.

1. A display panel, comprising:
a base substrate comprising a display region and a non-display region; wherein a plurality of sub-pixels are provided in the display region and comprise first sub-pixels and an edge virtual sub-pixel; at least one row of the plurality of sub-pixels comprises at least one edge virtual sub-pixel, and at least one column of the plurality of sub-pixels comprises at least one edge virtual sub-pixel;
a plurality of pixel drive units in a one-to-one correspondence with the first sub-pixels and the edge virtual sub-pixels; wherein the pixel drive units corresponding to the first sub-pixels are configured to drive the first sub-pixels to display a picture;
a color film substrate comprising a black matrix layer and a color filter layer formed on the color film substrate; wherein the black matrix layer is provided with a plurality of opening regions; the color filter layer comprises a plurality of first color filter layers, a plurality of second color filter layers and a plurality of third color filter layers; and an orthographic projection of the first color filter layers, the second color filter layers, and the third color filter layers on the color film substrate overlaps an orthographic projection of the opening regions on the color film substrate;
wherein an orthographic projection of the pixel drive unit corresponding to the edge virtual sub-pixel on the base substrate does not overlap an orthographic projection of the first color filter layers, the second color filter layers, and the third color filter layers on the base substrate; and the orthographic projection of the pixel drive unit corresponding to the edge virtual sub-pixel on the base substrate does not overlap an orthographic projection of the opening regions on the base substrate.

2. The display panel according to claim 1, wherein the edge virtual sub-pixel in a column of sub-pixels is closer to a corner edge of the display region than the first sub-pixels in the column of sub-pixels in a first direction; the edge virtual sub-pixel in a row of sub-pixels is closer to the corner edge of the display region than the first sub-pixels in the row of sub-pixels in a second direction.

3. The display panel according to claim 1, wherein a quantity of each column of the opening regions and a quantity of each row of the opening regions both reduce in a direction close to a corner edge of the display region;
wherein the color filter layer comprises a plurality of color filter units, each of the color filter units comprises: the first color filter layer, the second color filter layer and the third color filter layer; wherein the first color filter layer, the second color filter layer and the third color filter layer in each of the color filter units have the same orthographic projection on the base substrate;
wherein an area of each of the color filter units decreases gradually in the direction close to the corner edge of the display region.

4. The display panel according to claim 1, wherein the pixel drive unit comprises: a first sub-drive unit, and/or, a second sub-drive unit;
the first sub-drive unit comprises a first drive transistor; a gate electrode of the first drive transistor is coupled to a gate line, a first electrode of the first drive transistor is coupled to a data line, and a second electrode of the first drive transistor is coupled to a pixel electrode;
the second sub-drive unit comprises a second drive transistor; a gate electrode of the second drive transistor is coupled to the gate line, a first electrode of the second drive transistor is coupled to the data line, and a second electrode of the second drive transistor is coupled to the pixel electrode;
orthographic projections of the plurality of pixel drive units on the base substrate are of the same shape.

5. The display panel according to claim 1, wherein sub-pixels close to a corner edge of the display region are arranged in a stepped manner to form a plurality of pixel steps, each pixel step comprises at least one sub-pixel; and in some of the pixel steps, at least one edge virtual sub-pixel is provided every other pixel step.

6. The display panel according to claim 5, wherein the base substrate further comprises: a plurality of cascaded shift register units, a plurality of anti-electrostatic units, and at least one common electrode line; wherein each of the plurality of cascaded shift register units corresponds to one row of the sub-pixels respectively;
an orthographic projection of the anti-electrostatic units on the base substrate and an orthographic projection of the cascaded shift register units on the base substrate are respectively located on different sides of an orthographic projection of the common electrode line on the base substrate; the orthographic projection of the anti-electrostatic units on the base substrate is located between the orthographic projection of the common electrode line on the base substrate and an orthographic projection of the sub-pixels on the base substrate;
the sub-pixels in each pixel step are electrically connected to at least one of the anti-electrostatic units respectively; the anti-electrostatic unit is located at an end of the pixel step in a first direction, and the anti-electrostatic unit is located between up to two rows of sub-pixels in a second direction.

7. The display panel according to claim 6, wherein the anti-electrostatic unit corresponding to an nth pixel step is located at an end of the nth pixel step in the first direction, wherein n is an integer not less than 1.

8. The display panel according to claim 6, wherein the anti-electrostatic unit corresponding to an n^{th} pixel step is located at an end of an (n+i)^{th} pixel step in the first direction, wherein n is an integer not less than 1 and i is an integer not less than 1.

9. The display panel according to claim 6, wherein the anti-electrostatic unit corresponding to an n^{th} pixel step comprises a first anti-electrostatic unit located at an end of the n^{th} pixel step in the first direction and a first anti-electrostatic unit located at an end of an (n+i)^{th} pixel step in the first direction, wherein n is an integer not less than 1 and i is an integer not less than 1.

10. The display panel according to claim 6, wherein the base substrate further comprises: a plurality of data conduction signal lines; the sub-pixels in each pixel step are connected to the corresponding anti-electrostatic unit via the data conduction signal lines;
the data conduction signal line is arranged in an S-shape, and/or a folded line shape, and/or a lightning shape.

11. The display panel according to claim 5, wherein the shift register unit comprises: a first transistor, a second transistor, a third transistor, a fourth transistor, a fifth transistor, a sixth transistor, a seventh transistor, an eighth transistor, a ninth transistor, and a tenth transistor;
wherein the first transistor and the second transistor are opposite each other along the first direction; the third transistor and the fourth transistor are opposite each other along the first direction; an orthographic projection of the third transistor and the fourth transistor on the base substrate is between an orthographic projection of the first transistor on the base substrate and an orthographic projection of the fifth transistor on the base substrate; the sixth transistor and the seventh transistor are opposite each other along the first direction; an orthographic projection of the eighth transistor on the base substrate, an orthographic projection of the ninth transistor on the base substrate, and an orthographic projection of the tenth transistor on the base substrate are spaced apart in sequence in the second direction;
the first transistor, the second transistor, the third transistor, the fourth transistor, the fifth transistor, the sixth transistor, the seventh transistor, the eighth transistor, the ninth transistor, and the tenth transistor each comprises a plurality of active layers; the plurality of active layers are spaced apart from each other along the second direction; the plurality of active layers are spaced apart from each other along the second direction by a distance of no more than 3 microns;
a width of the active layer along the second direction is not greater than 5 microns.

12. The display panel according to claim 11, wherein the non-display region comprises: a silver paste region, a data fan-out line region, and a GOA signal line region;
the data fan-out line region is located between the display region and the GOA signal line region, the GOA signal line region is located between the data fan-out line region and the silver paste region, and the data fan-out line region is adjacent to the GOA signal line region;
a data fan-out signal line comprises: a first extension line and a first lift line;
an angle between the first extension line and the first lift line is a first included angle.

13. The display panel according to claim 12, wherein the first included angle ranges from 20 degrees to 35 degrees.

14. The display panel according to claim 12, wherein the GOA signal line region comprises a plurality of GOA signal lines; wherein the GOA signal line comprises: a second extension line and a second lift line;
the second extension line is provided in parallel with the first extension line, and the second lift line is provided in parallel with the first lift line.

15. The display panel according to claim 12, wherein a starting end of the data fan-out signal line is located on a lower side of the anti-electrostatic unit; the data fan-out signal line comprises a first sub-data fan-out signal line and a second sub-data fan-out signal line, wherein an extension direction of a starting end of the first sub-data fan-out signal line has an included angle of not equal to 90 degrees with the second direction, and/or, an extension direction of a starting end of the second sub-data fan-out signal line extends along the first direction.

16. The display panel according to claim 15, wherein an orthographic projection of the first sub-data fan-out signal line on the base substrate is closer to the display region than an orthographic projection of the second sub-data fan-out signal line on the base substrate.

17. The display panel according to claim 1, further comprising:
a gate conduction layer, on the base substrate;
a gate insulation layer, on a side of the gate conduction layer facing away from the base substrate;
a semiconductor layer, on a side of the gate insulation layer facing away from the base substrate; the semiconductor layer comprising a plurality of active layers;
an etch-blocking layer, on a side of the semiconductor layer facing away from the base substrate;
a source-drain layer, on a side of the etch-blocking layer facing away from the base substrate, comprising data lines, data fan-out lines, GOA signal lines, and data conduction signal lines;
a first insulation layer, on a side of the source-drain layer facing away from the base substrate;
a common electrode layer, on a side of the first insulation layer facing away from the base substrate;
a second insulation layer, on a side of the common electrode layer facing away from the base substrate;
a pixel electrode layer, on a side of the second insulation layer facing away from the base substrate.

18. The display panel according to claim 17, further comprising: a plurality of adapter units; the adapter unit comprising a first adapter hole and a second adapter hole; wherein the first adapter hole exposes the gate conduction layer, and the second adapter hole exposes the source-drain layer;
the pixel electrode layer and the gate conduction layer are in a jumper connection through the first adapter hole, and the pixel electrode layer and the source-drain layer are in a jumper connection through the second adapter hole.

19. The display panel according to claim 18, wherein the adapter unit is further used for connecting the GOA signal line to the shift register unit, and/or the adapter unit is within the shift register unit.

20. A display device comprising a display panel, wherein the display panel comprises:
a base substrate comprising a display region and a non-display region; wherein a plurality of sub-pixels are provided in the display region and comprise first sub-pixels and an edge virtual sub-pixel; at least one row of the plurality of sub-pixels comprises at least one edge virtual sub-pixel, and at least one column of the plurality of sub-pixels comprises at least one edge virtual sub-pixel;
a plurality of pixel drive units in a one-to-one correspondence with the first sub-pixels and the edge virtual sub-pixels; wherein the pixel drive units corresponding to the first sub-pixels are configured to drive the first sub-pixels to display a picture;
a color film substrate comprising a black matrix layer and a color filter layer formed on the color film substrate; wherein the black matrix layer is provided with a plurality of opening regions; the color filter layer comprises a plurality of first color filter layers, a plurality of second color filter layers and a plurality of third color filter layers; and an orthographic projection of the first color filter layers, the second color filter layers, and the third color filter layers on the color film substrate overlaps an orthographic projection of the opening regions on the color film substrate;
wherein an orthographic projection of the pixel drive unit corresponding to the edge virtual sub-pixel on the base substrate does not overlap an orthographic projection of the first color filter layers, the second color filter layers, and the third color filter layers on the base substrate; and the orthographic projection of the pixel drive unit corresponding to the edge virtual sub-pixel on the base substrate does not overlap an orthographic projection of the opening regions on the base substrate.
